(19) United States
(12) Patent Application Publication
(10) Pub. No.: US 2008/0318003 A1
(43) Pub. Date: Dec. 25, 2008

(54) Nanostructures and Method of Making the Same

(75) Inventors: Soo Jin Chua, Singapore (SG); Peng Chen, Singapore (SG); Yadong Wang, Singapore (SG)

Correspondence Address: ROTHWELL, FIGG, ERNST & MANBECK, P.C., 1425 K STREET, N.W., SUITE 800, WASHINGTON, DC, 20005, US

(73) Assignees: Agency for Science, Technology and Research, Singapore (SG); National University of Singapore, Singapore (SG)

(21) Appl. No.: 11/574,470

(22) PCT Filed: Aug. 31, 2004
(86) PCT No.: PCT/SG04/00274

§ 371 Date: Jan. 22, 2008

(51) Int. Cl. B32B 5/00; B05D 5/12; H01L 21/20; C23F 1/00

(52) U.S. Cl. 428/141; 427/58; 216/39; 438/483; 257/E21.09

(57) ABSTRACT

A method for fabricating nano-structures comprising providing a substrate for the growth of the nano-structures; providing a template having predetermined nano-patterns; providing at least one layer of mask material between the template and the substrate; transferring the nano-patterns from the template to the layer of mask material; and growing the nano-structures on the substrate in areas exposed through the nano-patterns in the layer of mask material by a bottom-up growth process.

### FIELD

The present invention relates broadly to a method of fabricating nano-structures, and to a nano-structure assembly.

### BACKGROUND

Low dimensional structures, such as semiconductor quantum wires and dots, give rise to new physical phenomena and technology. These low dimensional semiconductor structures have been applied to e.g. optoelectronic and electronic devices resulting in improved functionality of the devices. Examples of such devices are quantum dot (QD) laser diodes (LDs) and single-electron transistors.

To date, two approaches for the fabrication of semiconductor nano-scale dots are commonly adopted. The first approach is the heteroepitaxial growth of nano-scale dots directly on a heterogeneous structure, termed the bottom-up approach; the other approach is the direct patterning of nano-scale dots by lithographic methods, called the top-down approach.

In the bottom-up approach, the formation of nano-scale dots is controlled by Stranski-Krastanow (S-K) growth mode through self-organized processes in most cases, as well as re-crystallization by solid phase epitaxy (SPE). However, random spatial distribution of the nano-scale dots usually occurs in the self-organized processes. Thus, in order to achieve a regular array of nano-scale dots on large areas, a growth surface must be modified to increase the possibility of nucleation at selected sites, for example, by strain control. Furthermore, in self-organized semiconductor quantum dots, coherent island formation occurs during the growth of lattice-mismatched semiconductors.

In the top-down approach, the direct patterning by fine lithography technology provides a way for the fabrication of well-ordered nano-scale dots artificially. The lithography process can precisely control the size, density and distribution of the patterned nano-scale dots. However, the spatial resolution of the process is a major factor defining the size and density of the nano-scale dots. In some cases, the processing techniques, such as dry etching, cause additional damage to the crystal integrity of the patterned nano-structures, and at the same time, the high cost of the mask can be prohibitive.

In many material systems, porous structures can be formed by patterning caused by self-induced phenomena or artificial patterning. One example of self-constructed nano-templates is porous anodic aluminium oxide (AAO), and one example of artificial patterning is high-resolution lithography. AAO has stimulated great interest as a nano-structural template due to the self-organized formation of extremely well-aligned cylindrical pores and the tuneability of the interpore distance and pore diameter by simple variation of the anodisation parameters, such as temperature, voltage and electrolyte solution composition.

AAO templates are being widely used for the fabrication of nano-structures and devices made from different materials. The AAO templates exhibit good chemical resistance and physical stability. However, when the AAO template is directly applied as nano-scale mask for material growth in a metal-organic-chemical-vapour-deposition (MOCVD) system, depositions on the top of the template often block the nano-holes. As a result, growth of the nano-holes is hindered. This problem also impedes the application of nano-templates fabricated by other methods for producing nano-structures.

### SUMMARY

In one aspect, the present invention provides a method for fabricating nano-structures comprising: providing a substrate for the growth of the nano-structures; providing a template having predetermined nano-patterns; providing at least one layer of mask material between the template and the substrate; transferring the nano-patterns from the template to the layer of mask material; and growing the nano-structures on the substrate in areas exposed through the nano-patterns in the layer of mask material by a bottom-up growth process.

The nano-patterns on the template may be transferred to the layer of mask material by etching.

The patterns on the template may be transferred to the layer of mask material by dry etching or wet etching or dry etching.

The method may further comprise removing the template after transferring the nano-patterns from the template to the layer of mask material.

The method may further comprise removing the layer of mask material after the growth of the nano-structures is completed.

The layer of mask material and/or the template material may be chosen such that the nano-structures grow preferentially on the exposed substrate areas.

The nano-structures may comprise nano-doughnuts.

The nano-structures may comprise nano-dots.

The nano-structures may comprise nano-wires.

The nano-structures may comprise nano-rings.

The step of growing the nano-structures may comprise metal-organic-chemical-vapour-deposition (MOCVD) growth.

The step of growing the nano-structures may comprise MOCVD epitaxial growth.

The substrate may comprise gallium nitride.

The layer of mask material may comprise an insulator or a semiconductor material.

The layer of mask material may comprise silicon dioxide or silicon nitride.

The template may comprise anodic aluminium oxide.

The material for the growth of the nano-structures may comprise a semiconductor material.

The material for the growth of the nano-structures may comprise indium gallium nitride.

In another aspect, the present invention provides a nano-structure assembly comprising a substrate; and nano-structures formed on an unmodified growth surface of the substrate by a bottom-up growth process.

The nano-structure assembly may further comprise further nano-structures grown on the initially grown nano-structures.

The nano-structures may comprise nano-doughnuts.

The nano-structures may comprise nano-dots.

The nano-structures may comprise nano-wires.

The nano-structures may comprise nano-rings.

The substrate may comprise gallium nitride.

The layer of mask material may comprise an insulator or a semiconductor materials.

The layer of mask material may comprise silicon dioxide, or silicon nitride.

The template may comprise anodic aluminium oxide.

The material for the growth of the nano-structures may comprise a semiconductor material.

The material for the growth of the nano-structures may comprise indium gallium nitride.

### BRIEF DESCRIPTION OF THE DRAWINGS

The invention will now be further described by way of non-limiting examples, with reference to the accompanying drawings, in which:

FIG. 1 is a schematic representation of the cross section of a structure for fabricating a nano-template on a substrate in accordance with an embodiment of the present invention;

FIG. 2 is a schematic representation of the cross section of a structure for fabricating a nano-template on a substrate in accordance with another embodiment of the present invention;

FIG. 3 is a schematic representation of the cross section of a structure for fabricating semiconductor nano-structures in accordance with yet another embodiment of the present invention.

FIG. 4 is a cross section of the structure in FIG. 3, after nano-patterns on a nano-template is transferred to a mask material;

FIG. 5 is a cross section of the structure in FIG. 4, after the nano-template is removed.

FIG. 6 is a cross section of the structure shown in FIG. 5, showing the growth of semiconductor nano-structures on the substrate.

FIG. 7 is a cross section of the structure in FIG. 6, showing the semiconductor nano-structures on the substrate after the mask material is removed.

FIG. 8 is a scanning electron microscope (SEM) image of a porous AAO template in accordance with an embodiment of the present invention.

FIG. 9 is a graph showing the statistical size distribution of nano-holes derived from the SEM in FIG. 8.

FIG. 10 is an SEM image and an atomic force microscope (AFM) image of indium gallium nitride (InGaN) nano-doughnuts grown on a gallium nitride (GaN) surface using the AAO template in FIG. 8.

FIG. 11 is a graph showing the statistical size distribution of the nano-doughnuts in FIG. 10.

FIG. 12 is an SEM image of InGaN nano-dots grown on the GaN surface using the AAO template in FIG. 8.

FIG. 13 is a graph showing the photoluminescence spectrum of the InGaN nano-doughnuts in FIG. 10 at room temperature.

### DETAILED DESCRIPTION

Generally, the described embodiments provide integrated fabrication process for producing ordered semiconductor nano-structures on a substrate. The integrated process includes the transfer of nano-patterns from a nano-template to a mask-film on the substrate and growth of the semiconductor nano-structures on the patterned substrate surface.

It should be understood that when a template is referred to as being “on” another film, it can be directly on the film, or above the film for the purpose of being used as a nano-patterned mask. It should also be understood that when a template is referred to as being “on” another film, it may cover the entire film or a portion of the film.

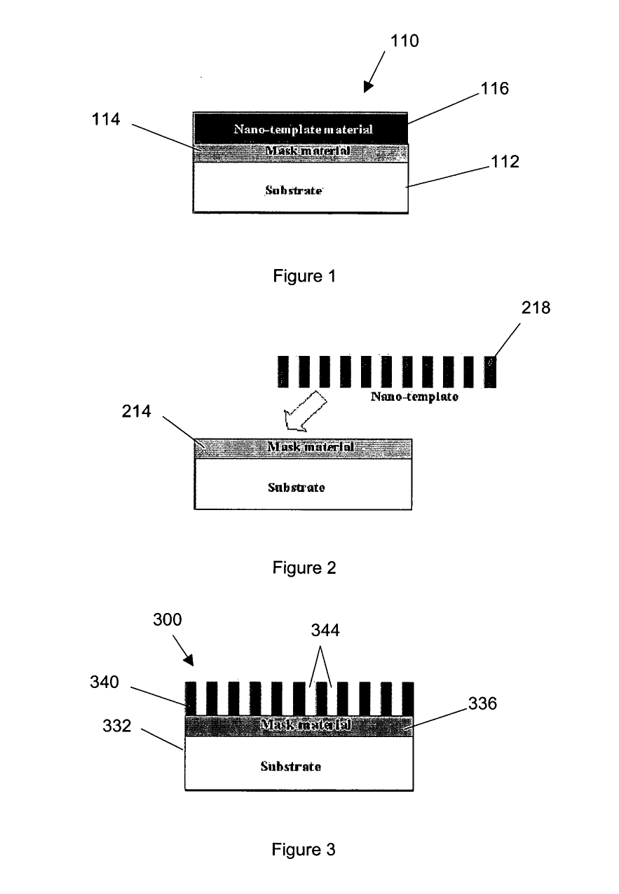

A schematic representation of the cross section of structure for fabricating a nano-template on a substrate in an example embodiment is shown in FIG. 1. In this embodiment, the structure 110 comprises a substrate 112, a mask material 114 and a layer of nano-template material 116. The nano-template material 116 is disposed on the substrate 112 with a layer of the mask material 114 (mask film) between the substrate 112 and the layer of nano-template material 116. A desired pattern is fabricated directly on the layer of nano-template material 116 to form a nano-template (not shown in FIG. 1). In an alternative embodiment, a nano-template 218 with a desired pattern is fabricated separately and then attached to the mask film 214, as shown in FIG. 2.

The cross section of a structure 300 for fabricating semiconductor nano-structures in accordance with another embodiment of the present invention is shown in FIG. 3. The structure 300 comprises a substrate 332, a mask material 336 on the substrate 332 and a nano-template 340 on the mask material 336. The nano-template 340 acts as a mask for the transfer of nano-patterns from the nano-template 340 to the mask material 336. A material such as anodic aluminium oxide (AAO) may be used as the nano-template 340. The nano-patterns on the nano-template 340 may, for example, be an array of nano-holes 344. The nano-patterns on the nano-template 340 are transferred to the to the mask material 336 by etching. In this embodiment, inductively coupled plasma (ICP) etching is used to transfer the nano-patterns from the nano-template 340 to the mask material 336. It should be understood that a variety of etching techniques can be adopted to achieve the nano-pattern transfer, for example, wet etching using chemical solvents and dry etching using ion reaction.

Portions of the mask material 336 that are directly under the nano-holes 344 are etched away. This results in the transfer of the nano-patterns from the nano-template 340 to the mask material 336. As a result, the nano-patterns on the nano-template 340 are “copied” to the mask material 336.

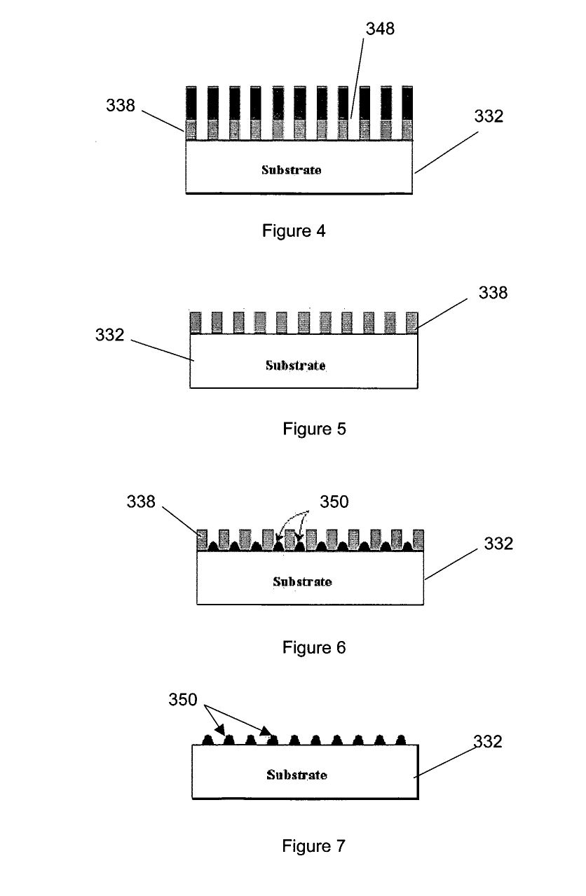

A patterned mask material 338 having an array of nano-holes 348 corresponding to the nano-holes 344 on the nano-template 340, is shown in FIG. 4. After the nano-pattern transfer, the nano-template 340 is removed (shown in FIG. 5) if it is not needed for further processing. After the nano-template 340 is removed, a semiconductor material such as indium gallium nitride (InGaN) is deposited onto the substrate 332 through the nano-holes 348 on the patterned mask material 338, and allowed to grow. The bottom-up growth of the InGaN semiconductor material can be carried out in various types of chambers or reactors which allow the deposition of semiconductor materials, for example, a metal-organic-chemical-vapour-deposition (MOCVD) chamber.

The substrate 332 is made of a material such as gallium nitride (GaN), and the mask material 338 is made of silicon dioxide (SiO₂) in the example embodiment. Silicon dioxide is used as it causes a differential growth rate of semiconductor material on the patterned mask material 338. It should be understood that the mask material 338 may be made of various other materials, for example, silicon nitride and other semiconductor materials, that allow the selective growth of semiconductor material on the substrate 332 and the mask material 338.

FIG. 6 shows the growth of semiconductor nano-structures 350 on the substrate 332. The crystalline semiconductor nano-structures 350 that are typically of less than 100 nanometers in diameter in the example embodiment are selectively grown on the substrate 332. The formation mechanism of the nano-structures 350 is based on adatom migration on the patterned substrate 332. Due to the selective growth of the semiconductor nano-structures 350 on the substrate 332 compared with on the patterned mask material 338, the semiconductor nano-structures 350 only forms on the surface of the substrate 332 but not on the surface of the patterned mask material 338. The Ga/In atoms do not bond to the SiO₂ surface. In this example, the grown rate of the InGaN semiconductor nano-structures 350 on the surface of the SiO₂ patterned mask material 338 is near zero.

After growth of the semiconductor nano-structures 350 is completed, the patterned mask material 338 can be removed if necessary (shown in FIG. 7). In some applications, e.g. where every unit (i.e. a dot or a doughnut, etc) of the semiconductor nano-structures is required to be individually insulated from electronic or optical connection, the insulating mask material 338 may remain on the substrate 332. The resulting semiconductor nano-structures 350 are arranged in an array according to the pattern of the nano-holes 348 on the patterned mask material 338. It should be noted that nano-structures of various shapes/configurations, for example, nano-dots, nano-wires, or nano-rings may be formed by using different growth conditions. Further, if the semiconductor nano-structures 350 are to be incorporated into a device, then other cap layers may be grown on the semiconductor nano-structures 350.

Further, by controlling growth conditions, such as the temperature, growth pressure, flow rate and growth duration, various semiconductor nano-structures, such as nano-dots and nano-doughnuts, can be achieved using the same nano-template pattern.

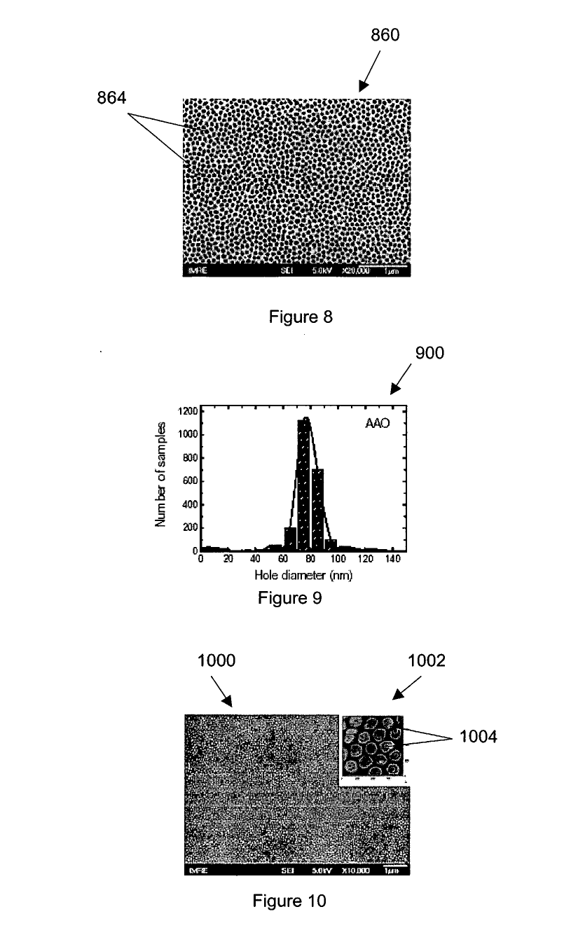

A scanning electron microscope (SEM) image of an exemplary porous AAO nano-template 860, with an array of nano-holes 864 patterned onto the nano-template is shown in FIG. 8. In this embodiment, a two-step anodisation process is used in the fabrication of the AAO nano-template 860. Firstly, an approximately 1-μm aluminium (Al) film was deposited onto the GaN epilayer by electron beam evaporation. Then the Al film was subjected to a first anodisation process in 0.3 M oxalic acid to anodise the Al film in the top 80% portion, and then the alumina layer is removed. The remaining 20% of the Al film was then subjected to the second anodisation process, wherein the Al film was fully anodised. After the second anodisation process, the sample was put into 5 wt % H₃PO₄ for 75 minutes at room temperature to enlarge the pore diameters of the nano-holes 864. It was observed that this two-step process results in a fairly uniform array of nearly parallel pores (for example, the nano-holes 864) and good adhesion of the porous AAO template 860 to the substrate (not shown in FIG. 8). Various other methods, including self-constructed nano-templates and artificial patterning such as high-resolution lithography can be used to fabricate a porous nano-template, such as the AAO nano-template 860. The statistical size distribution 900 of the nano-holes 864 is shown in FIG. 9. From the graph, it is observed that the nano-holes 864 in this embodiment generally have hole diameters between approximately 60 nm to 100 nm.

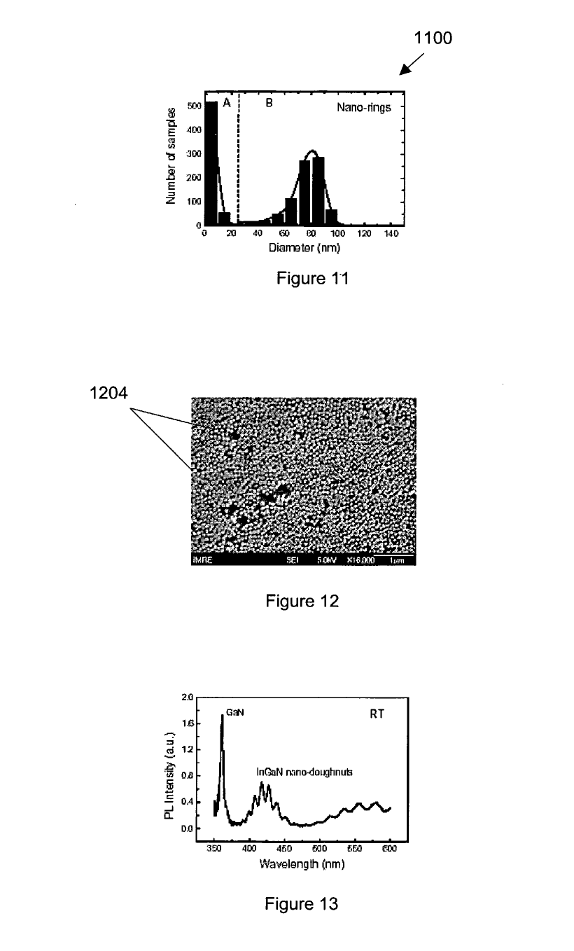

FIG. 10 shows an SEM image 1000 with an inlet 1002 showing an atomic force microscope (AFM) image of indium gallium nitride (InGaN) nano-doughnuts 1004 grown on a gallium nitride substrate surface (not shown) using the AAO nano-template 860. FIG. 11 shows a graph 1100 of the statistical size distributions of the nano-doughnuts 1004. Region A of the graph indicates the statistical diameter distribution of inner-hole diameter of the nano-doughnuts 1004 (FIG. 10), and region B of the graph 1100 shows the statistical distribution of the outer-ring diameters of the nano-doughnuts 1004 (FIG. 10). Comparing the graph in FIG. 9 with the graph in FIG. 11, it is observed that the outer-ring diameters of the nano-doughnuts 1004 are of approximately the same size as the nano-holes 864 in FIG. 8, showing precise formation of the nano-doughnuts 1004. The InGaN nano-structures (e.g. nano-doughnuts 1004) may be grown, for example, using high purity ammonia, trimethylgallium and trimethylindium in a MOCVD chamber at 750° C. It was observed that a growth duration of 3 minutes resulted in a nominated thickness of about 5 nanometers of growth of the InGaN nano-structures. The InGaN nano-doughnuts 1004 are formed due to the selective growth.

As mentioned earlier in the description, different types of semiconductor nano-structures can be produced from the same nano-patterns by controlling the growth conditions of semiconductor nano-structures. For example, by increasing the growth duration, InGaN nano-dots 1204 can be formed using the same nano-template as that for the nano-doughnuts 1004. This is shown in FIG. 12.

Although the InGaN nano-doughnuts 1004 shown in FIG. 10 are not covered by a cap layer, they still show strong photoluminescence at room temperature, as shown in FIG. 13. Typically, there is a depletion layer with thickness from about a few nanometers to about a few hundreds nanometers in the top region of semiconductor materials due to exposure to air. As a result, it is very difficult for electrons to stay in the top region of the semiconductor material. For conventional nano-structures on the surface of the semiconductor material, the photoluminescence of these nano-structures is very weak because most of the electrons are driven away from the top region of the semiconductor material. However, if there is a cap layer to bear the depletion layer, then most of the electrons can stay in the nano-structures, resulting in strong photoluminescence. In the present embodiment, the strong photoluminescence from uncapped InGaN nano-doughnuts 1004 shows a strong localisation effect in the nano-structures against the surface depletion.

The described embodiments can overcome the problems of producing a desired nano-structure on a substrate by using a nano-template that is not compatible to the growth of the nano-structures. Unlike the growth in the S-K mode, there is no specific compatibility requirement, such as lattice mismatch and strain, between the substrate and the nano-structure.

Further, the described embodiments can overcome the problem of incompatibility between the material of the nano-structures to be grown and the nano-template material, since the patterns on the nano-template are not used directly for the growth of the nano-structures, but are instead transferred onto the mask material before the growth or deposition of the material of the nano-structures. It should be appreciated that nano-patterns on the nano-template may be transferred to a second or third material which can act as the mask material for growth of the nano-structures.

The described embodiments have the advantages of a top-down technology to produce ordered nano-holes in a mask material based on the transfer of nano-patterns from a nanot-template. The patterned mask material in turn acts as a mask for subsequent MOCVD growth of nano-structures (bottom-up approach). The described embodiments also take the advantages of MOCVD epitaxial growth technology to grow high quality crystals.

The nano-structures grown in accordance with the described embodiments can be used for various purposes, such as for the fabrication of low-dimensional optoelectronic and microelectronic devices.

It will be appreciated that while only a few specific embodiments of the invention have been described herein for the purposes of illustration, various changes or modifications may be made without departing from the scope and spirit of the invention.

For example, it will be appreciated that in different embodiments other type of semiconductor materials may be used as the substrate, such as nitride compound semiconductors or other compound semiconductors.

1-28. (canceled)

29. A method for fabricating nano-structures comprising:
providing a substrate for the growth of the nano-structures;
providing a separately fabricated template having predetermined nano-patterns formed by self-induced penomena;
providing at least one layer of mask material between the template and the substrate;
transferring the nano-patterns from the template to the layer of mask material; and
growing the nano-structures on the substrate in areas exposed through the nano-patterns in the layer of mask material by a bottom-up growth process.

30. The method for fabricating nano-structures according to claim 29, wherein the nano-patterns on the template are transferred to the layer of mask material by etching.

31. The method of fabricating nano-structures according to claim 30, wherein the patterns on the template are transferred to the layer of mask material by dry or wet etching.

32. The method of fabricating nano-structures according to claim 29, further comprising removing the template after transferring the nano-patterns from the template to the layer of mask material.

33. The method of fabricating nano-structures according to claim 29, further comprising removing the layer of mask material after the growth of the nano-structures is completed.

34. The method of fabricating nano-structures according to claim 29, wherein the layer of mask material and/or the template material is chosen such that the nano-structures grow preferentially on the exposed substrate areas.

35. The method of fabricating nano-structures according to claim 29, wherein the nano-structures comprise nano-doughnuts.

36. The method of fabricating nano-structures according to claim 29, wherein the nano-structures comprise nano-dots.

37. The method of fabricating nano-structures according to claim 29, wherein the nano-structures comprise nano-wires.

38. The method of fabricating nano-structures according to claim 29, wherein the nano-structures comprise nano-rings.

39. The method of fabricating nano-structures according to claim 29, wherein the step of growing the nano-structures comprises metal-organic-chemical-vapour-deposition (MOCVD) growth.

40. The method of fabricating nano-structures according to claim 39, wherein the step of growing the nano-structures comprises MOCVD epitaxial growth.

41. The method of fabricating nano-structures according to claim 29, wherein the substrate comprises gallium nitride.

42. The method of fabricating nano-structures according to claim 29, wherein the layer of mask material comprises an insulator or a semiconductor material.

43. The method of fabricating nano-structures according to claim 42, wherein the layer of mask material comprises silicon dioxide or silicon nitride.

44. The method of fabricating nano-structures according to any claim 29, wherein the template comprises anodic aluminium oxide.

45. The method of fabricating nano-structures according to any claim 29, wherein the material for the growth of the nano-structures comprises a semiconductor material.

46. The method of fabricating nano-structures according to claim 42, wherein the material for the growth of the nano-structures comprises indium gallium nitride.

47. A nano-structure assembly comprising:
a substrate; and
nano-structures formed on a growth surface of the substrate by a bottom-up growth process, wherein the growth surface is not modified for lattice match to the nano-structures; and
wherein the nano-structures comprise nano-rings or -doughnuts.

48. The nano-structure assembly according to claim 47, further comprising further nano-structures grown on the initially grown nano-structures.

49. The nano-structure assembly according to claim 47, wherein the substrate comprises gallium nitride.

50. The nano-structure assembly according to claim 47, wherein a layer of mask material for the nano-structure comprises an insulator or a semiconductor materials.

51. The nano-structure assembly according to claim 50, wherein the layer of mask material comprises silicon dioxide, or silicon nitride.

52. The nano-structure assembly according to claim 47, wherein a template for the nano-structure comprises anodic aluminium oxide.

53. The nano-structure assembly according to claim 47, wherein the material for the growth of the nano-structures comprises a semiconductor material.

54. The nano-structure assembly according to claim 53, wherein the material for the growth of the nano-structures comprises indium gallium nitride.

55. A method of forming nano-structures on a substrate, the method comprising:
providing a mask having nano-patterns on the substrate; and
growing nano-rings or -doughnuts on areas of the substrate exposed through the nano-pattern.

56. The method as claimed in claim 55, wherein the mask is selected such that the nano-rings or -doughnuts are formed as a result of selective growth on the substrate compared with the patterned mask.
